(19) United States
(12) Patent Application Publication
(10) Pub. No.: US 2026/0136988 A1
(43) Pub. Date: May 14, 2026

(54) SEMICONDUCTOR PACKAGE AND METHOD OF MANUFACTURING THE SAME

(71) Applicants: Taiwan Semiconductor Manufacturing Company, Ltd., Hsinchu (TW); TSMC Arizona Corporation, Phoenix, AZ (US)

(72) Inventors: Xuewen Tang, Hsinchu (TW); Ji-Feng Ying, Hsinchu City (TW); Wen-Hsien CHUANG, Taipei City (TW); Jyun-Lin Wu, Hsinchu City (TW); Hao-Chun Liu, Hsinchu (TW)

(73) Assignees: Taiwan Semiconductor Manufacturing Company, Ltd., Hsinchu (TW); TSMC Arizona Corporation, Phoenix, AZ (US)

(21) Appl. No.: 18/946,989

(22) Filed: Nov. 14, 2024

(51) Int. Cl. H01L 23/04; H01L 21/56; H01L 23/00; H01L 23/06; H01L 23/31; H01L 23/498; H01L 25/18; H10B 80/00

(52) U.S. Cl. CPC H10W 76/12; H10W 74/012; H10W 74/117; H10W 74/121; H10W 74/15; H10W 76/17; H10B 80/00; H10W 72/0198; H10W 72/252; H10W 72/255; H10W 90/00; H10W 90/401; H10W 90/724; H10W 90/734

(57) ABSTRACT

A semiconductor package is provided. The semiconductor package includes an interposer, a die, a first encapsulant and a frame structure. The die is disposed on and electrically connected to the interposer. The first encapsulant is disposed on the interposer and laterally encapsulating the die. The frame structure is embedded in the first encapsulant.

### BACKGROUND

The semiconductor industry has experienced rapid growth due to continuous improvements in the integration density of various electronic components (e.g., transistors, diodes, resistors, capacitors, etc.). For the most part, this improvement in integration density has come from successive reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1, FIG. 2A and FIG. 3 through FIG. 8 are cross-sectional views schematically illustrating a process flow for fabricating a semiconductor package in accordance with some embodiments of the present disclosure.

FIG. 2B is a top view of FIG. 2A.

FIG. 2C is a perspective view schematically illustrating a frame structure in accordance with some embodiments of the present disclosure.

FIG. 9 through FIG. 14 are perspective views schematically illustrating various frame structures in accordance with some other embodiments of the present disclosure.

FIG. 15 is a flowchart illustrating a method of manufacturing a semiconductor package in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

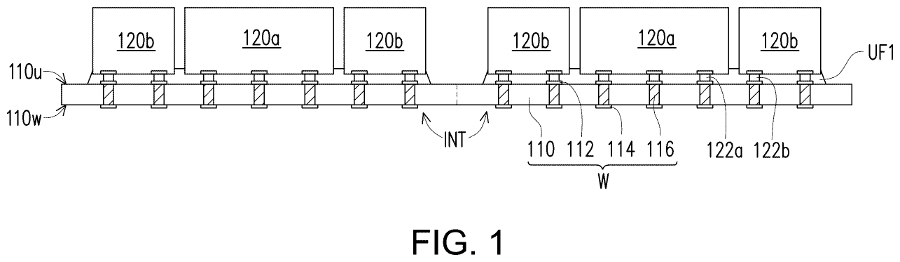

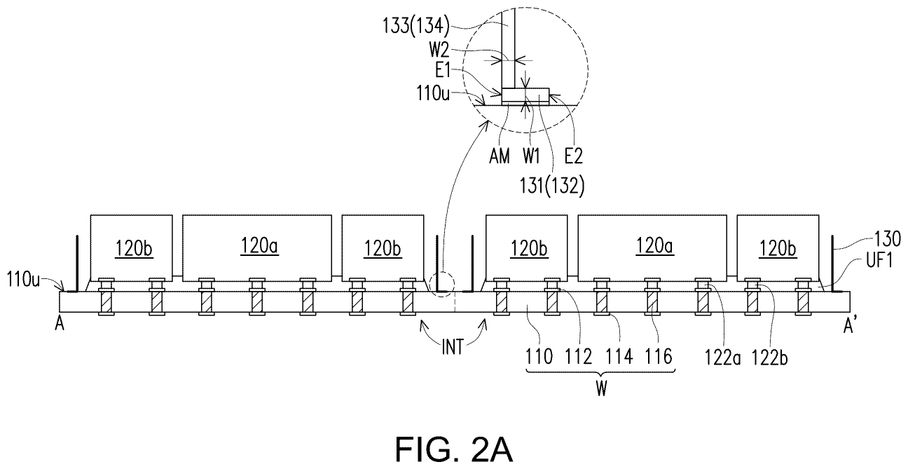

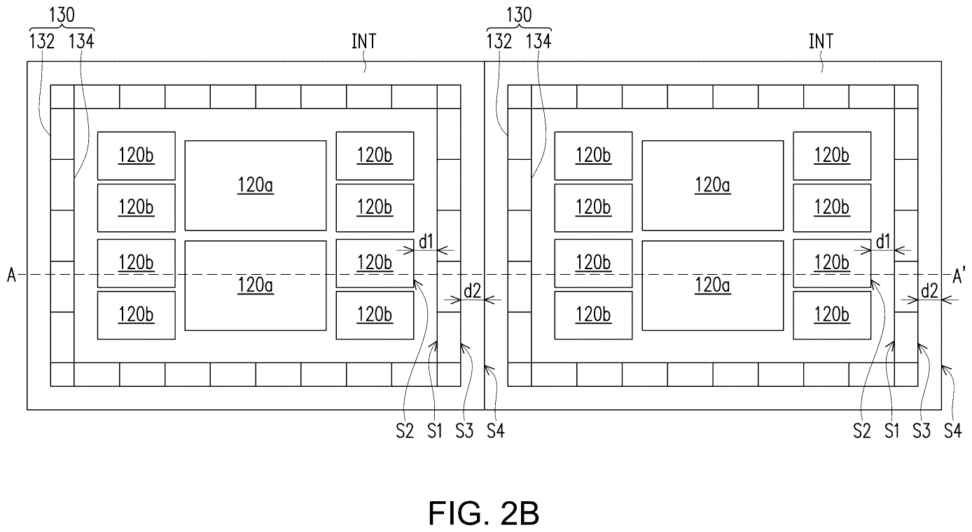

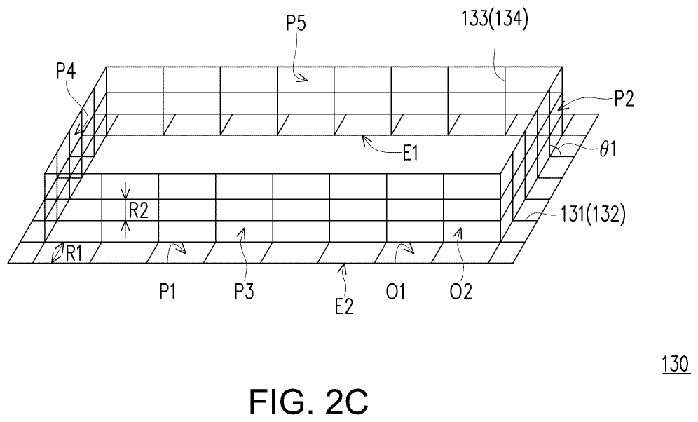

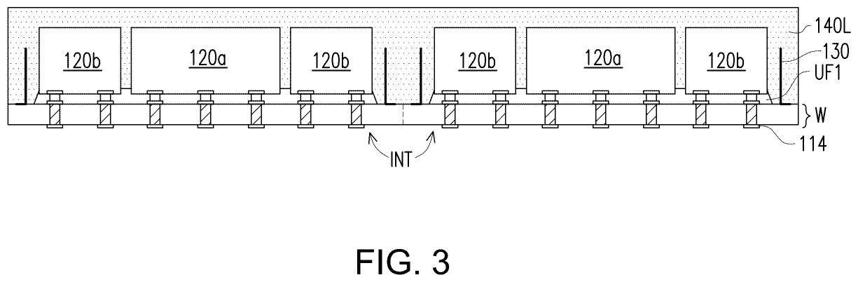

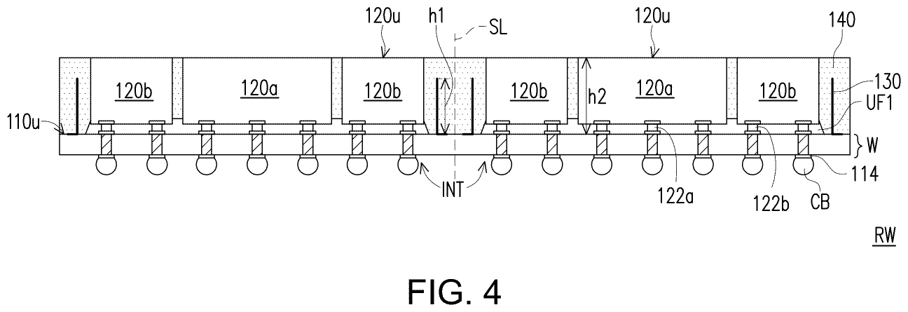

FIG. 1, FIG. 2A and FIG. 3 through FIG. 8 are cross-sectional views schematically illustrating a process flow for fabricating a semiconductor package in accordance with some embodiments of the present disclosure. FIG. 2B is a top view of FIG. 2A. FIG. 2A is a cross-sectional view taken along line A-A′ in FIG. 2B.

Referring to FIG. 1, an interposer wafer W including interposers INT arranged in array is provided. The interposer wafer W may be a silicon interposer wafer including multiple silicon interposers or other suitable semiconductor interposer wafer. The interposer wafer W may include a substrate 110, bump pads 112 disposed on an upper surface 110u of the substrate 110, bump pads 114 disposed on a lower surface 110w of the substrate 110, and through semiconductor vias (TSVs) 116 penetrating through the substrate 110, wherein the bump pads 112 are electrically connected to the bump pads 114 through the TSVs 116. Semiconductor dies 120a and semiconductor dies 120b are provided and bonded onto a surface of the interposer wafer W such that the semiconductor dies 120a and semiconductor dies 120b are electrically connected to the interposers INT of the interposer wafer W. In some embodiments, the semiconductor dies 120a and semiconductor dies 120b are electrically connected to the bump pads 112 of the interposer wafer W through conductive bumps 122a and conductive bumps 122b. The conductive bumps 122a are located between the semiconductor dies 120a and the bump pads 112, and the conductive bumps 122b are located between the semiconductor dies 120b and the bump pads 112. In some embodiments, the conductive bumps 122a may be formed on the semiconductor dies 120a before the semiconductor dies 120a are mounted on the interposer wafer W, and the conductive bumps 122b may be formed on the semiconductor dies 120b before the semiconductor dies 120b are mounted on the interposer wafer W. The conductive bumps 122a may be formed through a wafer-level bumping process performed on semiconductor wafers including the semiconductor dies 120a arranged in array, and the conductive bumps 122b may be formed through another wafer-level bumping process performed on semiconductor wafers including the semiconductor dies 120b arranged in array. In some embodiments, the semiconductor dies 120a includes logic dies, System-on-Chip (SoC) dies or other suitable semiconductor dies, and the semiconductor dies 120b includes High Bandwidth Memory (HBM) cubes each having stacked memory dies or other suitable semiconductor dies.

In some embodiments, the conductive bumps 122a and the conductive bumps 122b include micro bumps. The conductive bumps 122a and the conductive bumps 122b may each include a copper (Cu) pillar covered by a nickel (Ni) cap, and the nickel (Ni) cap may be electrically connected to the bump pads 112 through solder material. For example, the solder material includes Sn-Ag solder material or other suitable solder material.

After the semiconductor dies 120a and the semiconductor dies 120b are mounted on and electrically connected to the interposer wafer W through the conductive bumps 122a and the conductive bumps 122b, underfills UF1 are formed over the interposer wafer W to fill gaps between the semiconductor dies 120a and the interposer wafer W as well as gaps between the semiconductor dies 120b and the interposer wafer W. The conductive bumps 122a and the conductive bumps 122b are laterally encapsulated and protected by the underfills UF1 such that damage of the conductive bumps 122a and the conductive bumps 122b resulted from Coefficient of Thermal Expansion (CTE) mismatch between the interposer wafer W and the semiconductor dies 120a and 120b may be prevented. Accordingly, reliability of the conductive bumps 122a and the conductive bumps 122b may be improved.

Referring to FIG. 2A and FIG. 2B, a frame structure 130 is disposed onto the interposer INT to surround the semiconductor dies 120a and 120b. For example, the frame structure 130 is picked and placed onto the upper surface 110u of the substrate 110 of each interposer INT to surround the semiconductor dies 120a and semiconductor dies 120b on the same interposer INT. The frame structure 130 may be attached to the interposer INT through an adhesive material AM, which may include thermally conductive adhesive or epoxy-based adhesive or the like. In some embodiments, the adhesive material AM may be applied to a bottom surface of the frame structure 130 before the frame structure 130 is attached to the interposer INT. For example, the bottom surface of the frame structure 130 is sprayed (or dipped) with the adhesive material AM before the frame structure 130 is placed inside the gap between the semiconductor dies 120a and 120b. In this way, the frame structure 130 can be firmly stayed in place during downstream thermal processes, such as the baking process that solidify the encapsulation material.

During the placement of the frame structure 130, an alignment tool may be used to control the disposition precision of the frame structure 130. The size of the frame structure 130 may be adjusted according to the space surrounding the semiconductor dies 120a and 120b over the interposer INT. In some embodiments, the frame structure 130 surrounds all the semiconductor dies 120a and semiconductor dies 120b on the same interposer INT. In some embodiments, a minimum distance d1 between an inner sidewall S1 of the frame structure 130 and a sidewall S2 of the semiconductor die 120a or 120b is greater than or equal to 1 μm, such as 3 μm, 10 μm or 20 μm. In some other embodiments, the minimum distance d1 is between 1 μm and 15 μm, such as 3 μm, 8 μm or 12 μm. In some embodiments, a minimum distance d2 between an outer sidewall S3 of the frame structure 130 and an edge S4 of the interposer is greater than or equal to 1 μm, such as 3 μm, 10 μm or 20 μm. In some other embodiments, the minimum distance d2 is between 1 μm and 15 μm, such as 3 μm, 8 μm or 12 μm.

FIG. 2C is a perspective view schematically illustrating a frame structure in accordance with some embodiments of the present disclosure. Referring to FIG. 2A and FIG. 2C, the frame structure 130 may include a base mesh frame 132 and an interior mesh frame 134 attached to the base mesh frame 132. The base mesh frame 132 may have a ring profile and may be constructed in a substantially horizontal plane. For example, the base mesh frame 132 includes plural strips 131 distributed substantially in a horizontal plane P1, which is substantially parallel to the upper surface 110u of the interposer INT, and the strips 131 are connected with each other to constitute the skeleton of the base mesh frame 132. The base mesh frame 132 may be attached to the upper surface 110u of the interposer INT through the adhesive material AM.

The interior mesh frame 134 may have a ring profile that is substantially the same as that of the base mesh frame 132 such that a bottom surface of the interior mesh frame 134 can be attached to the base mesh frame 132. The interior mesh frame 134 may be connected to an inner edge E1 of the base mesh frame 132 adjacent to the semiconductor dies 120a and 120b. In some embodiments, the interior mesh frame 134 is attached to an outer edge E2 of the base mesh frame 132 opposite to the inner edge E1. The interior mesh frame 134 may be constructed in a plane that is substantially vertical to the horizontal plane P1 or the upper surface 110u of the interposer INT. For example, the interior mesh frame 134 includes plural strips 133 constituting the skeleton of the interior mesh frame 134, and the strips 133 are distributed in a vertical plane P2, a vertical plane P3, a vertical plane P4 and a vertical plane P5, all of which may be substantially vertical to the horizontal plane P1. The strips 133 may extend in either one of the vertical plane P2, vertical plane P3, vertical plane P4 and vertical plane P5, and may be connected with each other. The strip 133 of the interior mesh frame 134 may form an angle θ1 with the strip 131 of the base mesh frame 132. In some embodiments, the angle θ1 is approximately between 80° and 100°, such as 90°. In some other embodiments, the strips 133 of the interior mesh frame 134 is connected to joints located between the inner edge E1 and the outer edge E2 of the base mesh frame 132.

The shape of the ring profile of the base mesh frame 132 or the interior mesh frame 134 may be adjusted according to the arrangement of the semiconductor dies 120a and 120b. In some embodiments, the ring profile of the base mesh frame 132 or the interior mesh frame 134 has a polygon shape, such as a rectangle. In other embodiments, the ring profile of the base mesh frame 132 or the interior mesh frame 134 may have an ellipse or circular shape.

The distribution density of the strips 131 and the strips 133 may be adjusted according to the position with respect to the semiconductor dies 120a and 120b. Alternatively, the distribution density of the strips 131 and the strips 133 may be adjusted according to the incidence of encapsulant crack at various regions with respect to the semiconductor dies 120a and 120b. For example, the strips 131 and the strips 133 are distributed densely where a high incidence of encapsulant crack is detected (such as at corners of the base mesh frame 132 and the interior mesh frame 134) and sparsely where a low incidence of encapsulant crack is detected (such as at sides between the corners of the base mesh frame 132 and the interior mesh frame 134). The strip 131 may have a width W1 and the strip 133 may have a width W2, which may be the same as or different from the width W1. In some embodiments, the width W1 or the width W2 is less than 20 μm. In some other embodiments, the width W1 or the width W2 is between 1 μm and 10 μm, such as 3 μm, 5 μm or 8 μm.

The base mesh frame 132 may have holes O1 formed between the strips 131. The interior mesh frame 134 may have holes O2 formed between the strips 133. In some embodiments, most of the holes O1, O2 have a regular shape, such as a polygon (for example, rectangle, diamond, pentagon, hexagon, heptagon or octagon), an ellipse or a circle. In some embodiments, the holes O1, O2 have various irregular shapes. The size of the holes O1, O2 is designed to not negatively impact the subsequent gap filling process of the encapsulation material. For example, the hole O1 has a minimum inner diameter R1, which is defined as the shortest distance between opposite strips 131 surrounding the hole O1, and the hole O2 has a minimum inner diameter R2, which is defined as the shortest distance between opposite strips 133 surrounding the hole O2. The minimum inner diameter R1 may be the same as or different from the minimum inner diameter R2. In some embodiments, the minimum inner diameter R1 or the minimum inner diameter R2 is greater than or equal to 1 μm, such as 5 μm, 10 μm or 20 μm.

The frame structure 130 may be composed of metallic or non-metallic materials. In some embodiments, the frame structure 130 may comprise a metallic or an alloy material, such as copper, copper alloy, stainless steel, among other examples. In some embodiments, the frame structure 130 may comprise a polymer material, such as polyethylene, polypropylene, polyester (e.g., PET), polytetrafluoroethylene, Nylon, among other examples. The frame structure 130 may be formed separately by 3D printing, injection molding or any other suitable methods.

Referring to FIG. 3, an encapsulation material 140L is formed over the interposer wafer W to encapsulate the semiconductor dies 120a, the semiconductor dies 120b and the frame structure 130. The minimum inner diameter R1, R2 of the holes O1, O2 in the frame structure 130 is greater than the maximum diameter of particles in the encapsulation material 140L to facilitate the gap filling of the encapsulation material 140L in the frame structure 130. As a result, the strips 131, 133 of the frame structure 130 may be configured in the encapsulation material 140L, creating a network that physically holds the encapsulation material 140L together, so as to prevent the encapsulation material 140L from crack and/or to prevent delamination between the encapsulation material 140L and the semiconductor dies 120a and 120b during subsequent processes. In other words, the frame structure 130 may possess reinforcement function to hold the encapsulation material 140L and prevent the encapsulation material 140L from crack throughout the manufacturing process, especially during the thermal and mechanical stress cycle, thereby improving reliability of the completed semiconductor package.

The encapsulation material 140L may be formed by an over-molding process or a deposition process. The over-molding process or deposition process may be carried out at a temperature below a glass transition temperature (of the polymer material) or a melting point (of the metallic material) of the frame structure 130 so that the frame structure 130 can maintain its form during the over-molding process or the deposition process. In some embodiments, an encapsulation material 140L such as epoxy resin is formed on the interposer wafer W to cover the upper surfaces and sidewalls of the semiconductor dies 120a and 120 b through an over-molding process at a temperature between 80° C. and 180° C. In some alternative embodiments, an encapsulation material 140L such as tetraethoxysilane (TEOS) formed oxide is formed on the interposer wafer W to cover the upper surfaces and sidewalls of the semiconductor dies 120a and 120b through a chemical vapor deposition (CVD) process at a temperature between 150° C. and 280° C.

Referring to FIG. 4, a removal process may be performed on the encapsulation material 140L. In some embodiments, a grinding process, a chemical mechanical polishing (CMP) process or other suitable removal process is performed to remove portions of the encapsulation material 140L until the upper surfaces 120u of the semiconductor dies 120a and 120b are revealed. After performing the removal process, an encapsulant 140 is formed to laterally encapsulate the semiconductor dies 120a and 120b and the frame structure 130, and the top surface of the encapsulant 140 is substantially level with the upper surfaces 120u of the semiconductor dies 120a and 120b. The frame structure 130 may have a height h1. In some embodiments, after performing the removal process, the height h1 of the frame structure 130 is less than a height h2 between an upper surface 120u of the semiconductor dies 120a and 120b and an upper surface 110u of the interposer INT, so the frame structure 130 is covered by the encapsulant 140 and not visible after the formation of the encapsulant 140.

In some embodiments, during the removal process of the encapsulation material 140L, the encapsulation material 140L, the semiconductor dies 120a and the semiconductor dies 120b are partially removed such that the thickness of the semiconductor dies 120a and the semiconductor dies 120b is reduced, and the frame structure 130 is still invisible after the formation of the encapsulant 140 and embedded in the encapsulant 140.

A wafer-level bumping process may be performed such that conductive bumps CB are formed over bump pads 114 of the interposer wafer W. In some embodiments, the wafer-level bumping process for forming the conductive bumps CB is performed before formation of the encapsulant 140. In some alternative embodiments, the wafer-level bumping process for forming the conductive bumps CB is performed after formation of the encapsulant 140.

After forming the encapsulant 140 and the conductive bumps CB, a reconstructed wafer RW including the interposer wafer W, the semiconductor dies 120a, the semiconductor dies 120b, the underfills UF1, the frame structure 130, the encapsulant 140, and the conductive bumps CB is formed.

Referring to FIG. 4 and FIG. 5, a wafer saw process is then performed along scribe lines SL such that the reconstructed wafer RW is singulated into multiple singulated structures SS. The singulated structures SS may each include an interposer INT, at least one semiconductor die 120a, at least one semiconductor dies 120b, conductive bumps 122a, conductive bumps 122b, an underfill UF1, a frame structure 130, an encapsulant 140', and conductive bumps CB. The conductive bumps 122a are electrically connected between the semiconductor die 120a and the interposer INT. The conductive bumps 122b are electrically connected between the semiconductor die 120b and the interposer INT. The underfill UF1 laterally encapsulates the conductive bumps 122a and 122b. The underfill UF1 may further cover sidewalls of the semiconductor dies 120 a and 120 b. The encapsulant 140′ laterally encapsulates the semiconductor dies 120a and 120b and the frame structure 130, wherein sidewalls of the encapsulant 140′ are substantially aligned with sidewalls of the interposer INT. Furthermore, the conductive bumps 122a and 122b are disposed on a surface (e.g., an upper surface) of the interposer INT, and the conductive bumps CB are disposed on another surface (e.g., a lower surface) of the interposer INT.

Referring to FIG. 6, a wiring substrate 150 including conductive terminals 152 formed thereon is provided. In some embodiments, the wiring substrate 150 includes a dielectric core layer, build-up or laminated dielectric layers stacked over opposite surfaces of the dielectric core layer, conductive wiring layers embedded in the build-up or laminated dielectric layers, and conductive vias penetrating through the dielectric core layer and the build-up or laminated dielectric layers. The conductive terminals 152 is formed on a lower surface of the wiring substrate 150 and electrically connected to the bottommost conductive wiring layer of the wiring substrate 150.

At least one of the singulated structures SS singulated from the reconstructed wafer RW illustrated in FIG. 5 may be picked-up and placed on an upper surface of the wiring substrate 150. The singulated structure SS is electrically connected to the conductive wirings of the wiring substrate 150 through the conductive bumps CB. After the at least one singulated structure SS is mounted on the wiring substrate 150, an underfill UF2 may be formed to fill a gap between the wiring substrate 150 and the interposer INT of the singulated structure SS. The conductive bumps CB are laterally encapsulated and protected by the underfill UF2 such that damage of the conductive bumps CB resulted from CTE mismatch between the interposer INT and the wiring substrate 150 may be prevented. Accordingly, reliability of the conductive bumps CB may be improved.

In some embodiments, the underfill UF2 not only fills the gap between the wiring substrate 150 and the interposer INT of the singulated structure SS, but also covers sidewalls of the singulated structure SS. As illustrated in FIG. 6, the underfill UF2 not only fills the gap between the wiring substrate 150 and the interposer INT of the singulated structure SS, but also covers sidewalls of the interposer INT and sidewalls of the encapsulant 140′.

Referring to FIG. 7, an encapsulation material is formed over the wiring substrate 150 to cover the underfill UF2 and the singulated structure SS mounted on the wiring substrate 150. The encapsulation material may be formed by an over-molding process or a deposition process followed by a removal process. In some embodiments, an encapsulation material such as epoxy resin is formed on the interposer wafer W to cover the back surfaces and sidewalls of the singulated structure SS through an over-molding process, and a grinding process, a chemical mechanical polishing (CMP) process or other suitable removal process is then performed to remove portions of the epoxy resin until the back surfaces of the semiconductor dies 120a and 120b in the singulated structure SS are revealed. In some alternative embodiments, an encapsulation material such as tetraethoxysilane (TEOS) formed oxide is formed on the interposer wafer W to cover back surfaces and sidewalls of the singulated structure SS through a chemical vapor deposition (CVD) process, and a grinding process, a CMP process or other suitable removal process is then performed to remove portions of the TEOS formed oxide until the back surfaces of the semiconductor dies 120a and 120b in the singulated structure SS are revealed. After performing the above-mentioned removal process, an encapsulant 160 is formed, and the top surface of the encapsulant 160 is substantially level with the upper surfaces 120u of the semiconductor dies 120a and 120b in the singulated structure SS.

Furthermore, as illustrated in FIG. 7, the top surface of the encapsulant 160 is substantially level with the top surface of the encapsulant 140′ and the upper surfaces 120 u of the semiconductor dies 120 a and 120 b, and sidewalls of the encapsulant 160 are substantially aligned with sidewalls of the wiring substrate 150. In some alternative embodiments, the top surface of the encapsulant 160 is substantially level with the top surface of the encapsulant 140′ and the upper surfaces 120 u of the semiconductor dies 120 a and 120b, and sidewalls of the encapsulant 160 keep a lateral distance from sidewalls of the wiring substrate 150.

Referring to FIG. 8, after forming the encapsulant 160, a thermal interface material (TIM) 170 and an adhesive 180 are applied to cover the singulated structure SS and the encapsulant 160. The thermal interface material 170 may cover the top surface of the singulated structure SS and a portion of the top surface of the encapsulant 160, and the adhesive 180 may cover the rest portion of the top surface of the encapsulant 160. The material of the thermal interface material 170 may include metallic TIM, such as indium (In) sheet or film, indium foil, indium solder, silver (Ag) paste, silver alloy or combination thereof. The thermal interface material 170 may also be polymer-based TIM with thermal conductive fillers. Applicable thermal conductive filler materials may include aluminum oxide, boron nitride, aluminum nitride, aluminum, copper, silver, indium, a combination thereof, or the like. The thermal interface material 170 may include film-based or sheet-based material such as sheet with synthesized carbon nano-tube (CNT) structure integrated into the sheet, thermal conductive sheet with vertically oriented graphite fillers or the like, and the material of the adhesive 180 may include thermally conductive adhesive or epoxy-based adhesive or the like. A lid 190 is then provided over and attached to the thermal interface material 170 and the adhesive 180. The lid 190 is thermally coupled to the upper surfaces 120u of the semiconductor dies 120a and 120b in the singulated structure SS through the thermal interface material 170, and the lid 190 is adhered with the top surface of the encapsulant 160 through the adhesive 180. The material of the lid 190 may include copper, aluminum, cobalt, copper coated with nickel, stainless steel, tungsten, silver diamond, aluminum silicon carbide or the like. Furthermore, the lid 190 may serve and function as a heat sink.

In some alternative embodiments, not illustrated in figures, the top surface of the singulated structure SS and the top surface of the encapsulant 160 are covered by the thermal interface material 170, and formation of the adhesive 180 is omitted. In other words, the lid 190 is attached to the singulated structure SS and the encapsulant 160 through the thermal interface material 170.

As illustrated in FIG. 8, after forming the lid 190, a Chip-on-Wafer-on-Substrate (CoWoS) package structure 10 is formed. The CoWoS package structure 10 includes a wiring substrate 150, a singulated structure SS mounted on the wiring substrate 150, an underfill UF2 between the wiring substrate 150 and the singulated structure SS, an encapsulant 160 disposed on the wiring substrate 150, and a lid 190 over the singulated structure SS. The singulated structure SS may be electrically connected to the wiring substrate 150 through conductive bumps CB. The singulated structure SS includes an interposer INT disposed on and electrically connected to the wiring substrate 150, at least one semiconductor dies 120a and at least one semiconductor dies 120b disposed on the interposer INT, an underfill UF1 between the interposer INT and the semiconductor dies 120a and 120b, a frame structure 130 attached to the interposer INT and surrounding the semiconductor dies 120a and 120b, and an encapsulant 140′ disposed on the interposer INT. The semiconductor dies 120a may be electrically connected to the interposer INT through the conductive bumps 122a, and the semiconductor dies 120b may be electrically connected to the interposer INT through the conductive bumps 122b. The frame structure 130 may have a ring pattern surrounding the semiconductor dies 120a and 120b in a top view, as shown in FIG. 2B.

The semiconductor dies 120a and 120b and the frame structure 130 are laterally encapsulated by the encapsulant 140′. The frame structure 130 has a glass transition temperature higher than the molding temperature of the encapsulant 140′. The upper surfaces 120u of the semiconductor dies 120a and 120b are not covered by the encapsulant 140′, while the frame structure 130 is covered by the encapsulant 140′. The frame structure 130 is embedded in the encapsulant 140′ and encapsulated by the encapsulant 140′. The semiconductor dies 120a and 120b, the frame structure 130 and the encapsulant 140′ are laterally encapsulated by the encapsulant 160. In some embodiments, a top surface of the encapsulant 140′ is substantially level with a top surface of the encapsulant 160. In some other embodiments, a top surface of the frame structure 130 is below the top surface of the encapsulant 140′. The underfill UF1 may be laterally encapsulated by the encapsulant 140′. The frame structure 130 embedded in the encapsulant 140′ may further surround the underfill UF1. In some embodiments, the underfill UF2 is vertically overlapped with the frame structure 130 and laterally encapsulated by the encapsulant 160.

The lid 190 is disposed on the semiconductor dies 120a and 120b, the encapsulant 140′ and the encapsulant 160. Sidewalls of the lid 190 are substantially aligned with sidewalls of the encapsulant 160 and sidewalls of the wiring substrate 150. In some embodiments, the CoWoS package structure 10 further includes a thermal interface material 170 and an adhesive 180, wherein the thermal interface material 170 is disposed between the semiconductor dies 120a and 120b and the lid 190, and the adhesive 180 is disposed between the encapsulant 160 and the lid 190.

The lid 190 may be a metallic plate with favorable thermal conductivity and structural strength. Since the singulated structure SS is laterally encapsulated by the encapsulant 160, warpage of the CoWoS package structure 10 is controlled. Furthermore, delamination issue of the adhesive 180 as well as crack issue of the conductive bumps 122 a and 122b resulted from the warpage of the CoWoS package structure 10 may be minimized. In addition, due to the reinforcement of the frame structure 130, the encapsulant 140′ is prevented from crack and delamination during the thermal and mechanical stress cycle, thereby improving reliability of the CoWoS package structure 10.

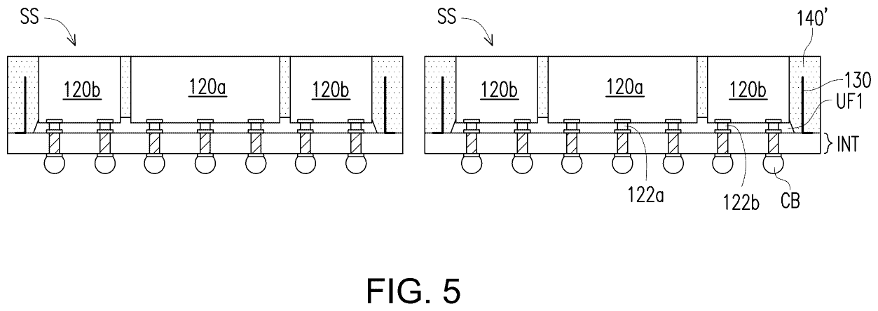

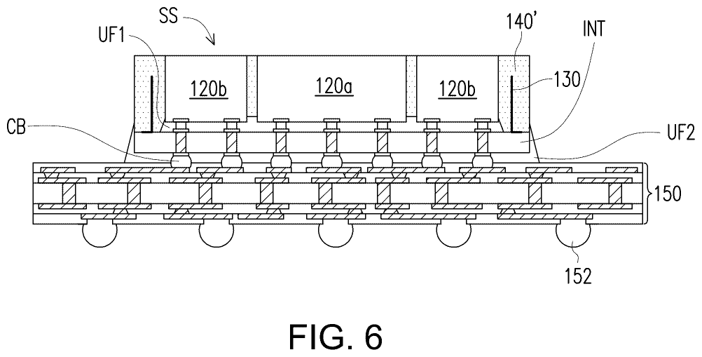

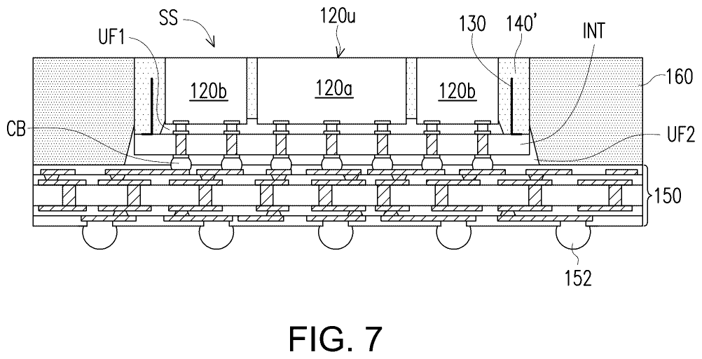

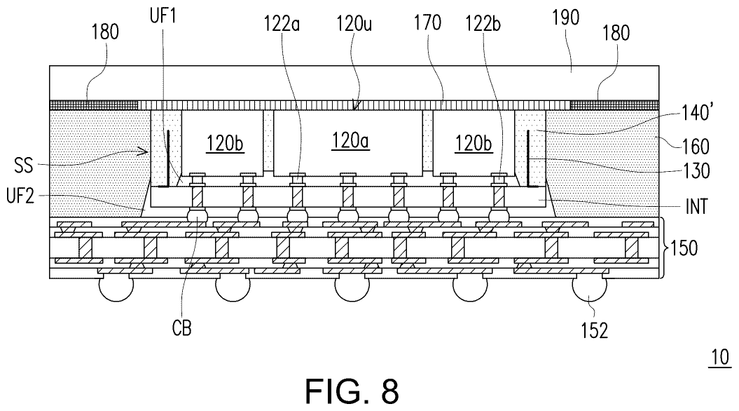

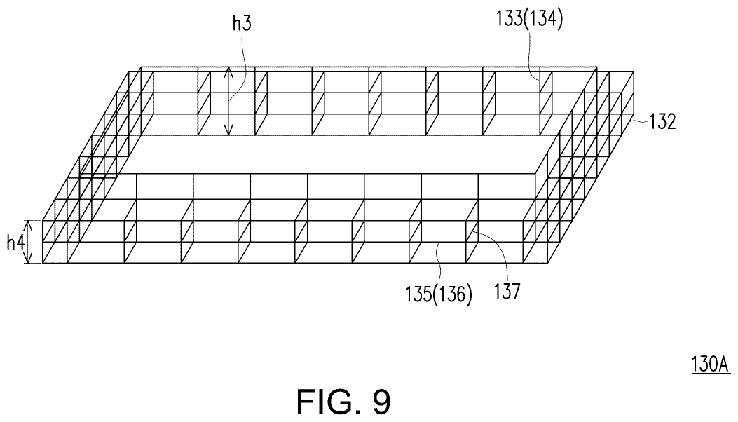

FIG. 9 through FIG. 13 are perspective views schematically illustrating various frame structures 130A-130E in accordance with some other embodiments of the present disclosure.

Referring to FIG. 9, a frame structure 130A as shown in FIG. 9 is similar to the frame structure 130 as shown in FIG. 2C except that the frame structure 130A further includes an exterior mesh frame 136 attached to the outer edge E2 of the base mesh frame 132. The exterior mesh frame 136 may be substantially parallel to the interior mesh frame 134. In some embodiments, the frame structure 130A is attached to the upper surfaces 110u of the interposer INT as shown in FIG. 2A such that the interior mesh frame 134 is located between the semiconductor dies 120b and the exterior mesh frame 136. In some embodiments, the interior mesh frame 134 has a height h3 greater than a height h4 of the exterior mesh frame 136. In some embodiments, the frame structures 130A further include plural strips 137 connecting the strips 135 of the exterior mesh frame 136 with the strips 133 of the interior mesh frame 134.

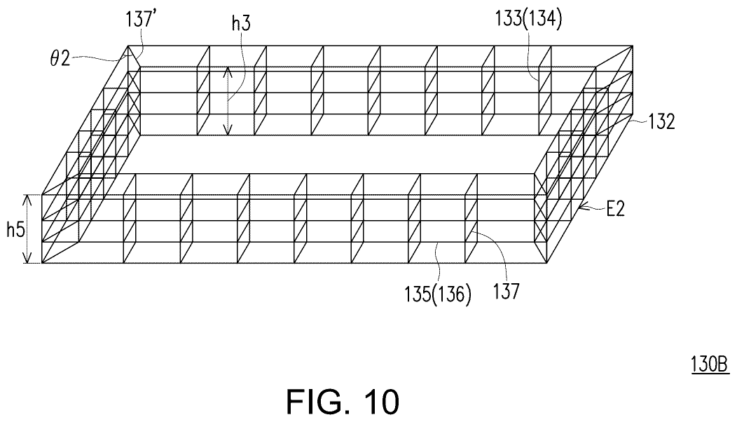

Referring to FIG. 10, a frame structure 130B as shown in FIG. 10 is similar to the frame structure 130A as shown in FIG. 9 except that the exterior mesh frame 136 may have a height h5 approximately equal to the height h3 of the interior mesh frame 134. In some embodiments, the frame structure 130B further includes corner strips 137′ connecting the strips 133 of the interior mesh frame 134 with the strips 135 of the exterior mesh frame 136. The corner strip 137′ may form an angle θ2 with the strip 135 of the exterior mesh frame 136. In some embodiments, the angle θ2 is approximately between 30° and 60°, such as approximately 45°.

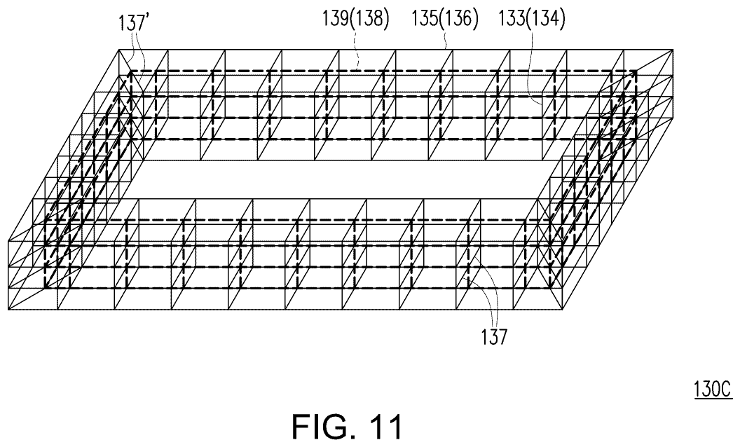

Referring to FIG. 11, a frame structure 130C as shown in FIG. 11 is similar to the frame structure 130B as shown in FIG. 10 except that the frame structure 130C further includes one or more intermediate mesh frames 138 disposed between the interior mesh frame 134 and the exterior mesh frame 136. The intermediate mesh frames 138 is depicted in bold dashed lines for better clarity, as shown in FIG. 11. The intermediate mesh frames 138 may have a structure similar to that of the interior mesh frame 134 or the exterior mesh frame 136. In some embodiments, the interior mesh frame 134, the exterior mesh frame 136 and the intermediate mesh frames 138 have substantially equal height. In some embodiments, the strips 137, 137′ connects the strips 139 of the intermediate mesh frames 138 with the strips 135 of the exterior mesh frame 136 as well as the strips 133 of the interior mesh frame 134.

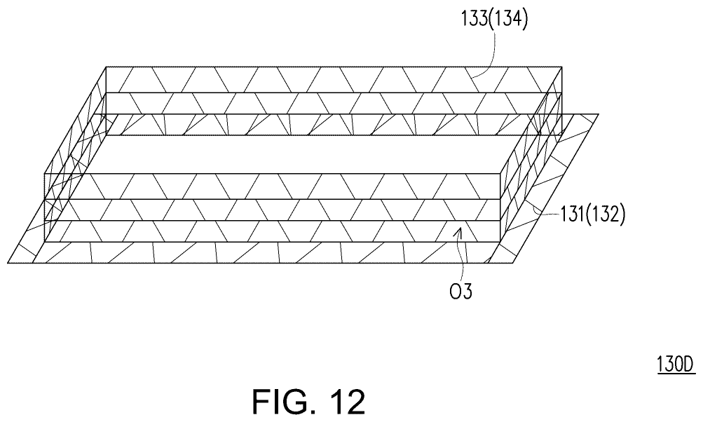

Referring to FIG. 12, a frame structure 130D as shown in FIG. 12 is similar to the frame structure 130 as shown in FIG. 2C except that the holes O3 formed between the stripes 133 of the interior mesh frame 134 or between the stripes 131 of the base mesh frame 132 may have a parallelogram shape.

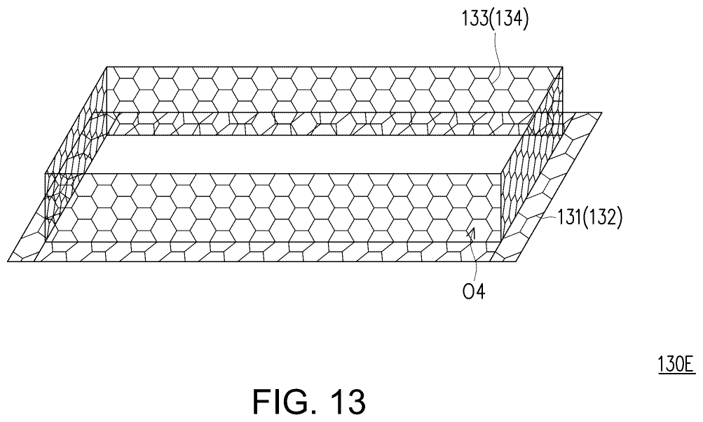

Referring to FIG. 13, a frame structure 130E as shown in FIG. 13 is similar to the frame structure 130 as shown in FIG. 2C except that the holes O4 formed between the stripes 133 of the interior mesh frame 134 or between the stripes 131 of the base mesh frame 132 may have a hexagon shape. In some embodiments, the frame structure 130E has a honeycomb-like structure.

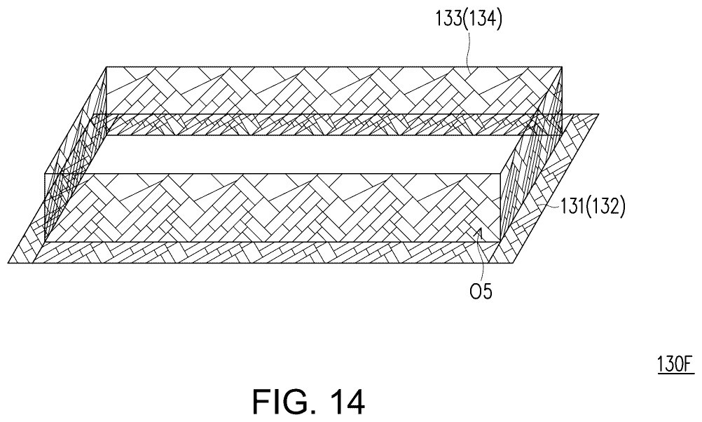

Referring to FIG. 14, a frame structure 130F as shown in FIG. 14 is similar to the frame structure 130 as shown in FIG. 2C except that the holes O5 formed between the stripes 133 of the interior mesh frame 134 or between the stripes 131 of the base mesh frame 132 may have irregular shapes. In some embodiments, the holes O5 of the frame structure 130F have various dimensions.

The shape and the dimension of the frame structures 130 and 130A-130E are not limited in the present disclosure. Other types of frame structures which are not illustrated in FIG. 2C and FIG. 9 through FIG. 13 may be applied as well.

In the above-mentioned embodiments, since the frame structures 130 and 130A-130E are embedded in the encapsulant 140', crack issues of the encapsulant 140′ surrounding the semiconductor dies 120a and 120b may be eliminated. Furthermore, delamination issues happened between encapsulant 140′ and the semiconductor dies 120 a and 120b may be minimized. Accordingly, reliability of the package structures 10 may be improved.

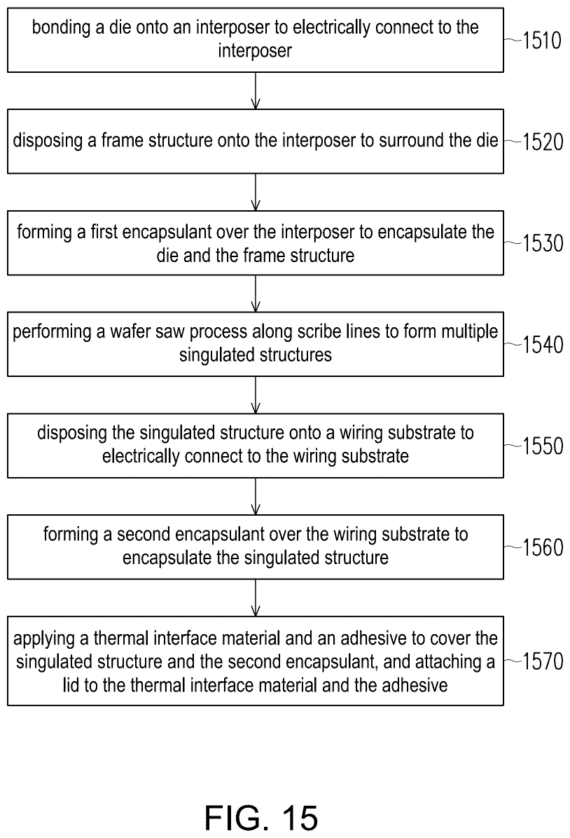

FIG. 15 is a flowchart illustrating a method of manufacturing a semiconductor package in accordance with some embodiments. Although the method is illustrated and/or described as a series of acts or events, it will be appreciated that the method is not limited to the illustrated ordering or acts. Thus, in some embodiments, the acts are carried out in different orders than illustrated, and/or are carried out concurrently. Further, in some embodiments, the illustrated acts or events are subdivided into multiple acts or events, which may be carried out at separate times or concurrently with other acts or sub-acts. In some embodiments, some illustrated acts or events are omitted, and other un-illustrated acts or events are included.

At act 1510, a die is bonded onto an interposer to electrically connect to the interposer. FIG. 1 illustrates a cross-sectional view corresponding to some embodiments of act 1510.

At act 1520, a frame structure is disposed onto the interposer to surround the die. FIG. 2A illustrates a cross-sectional view corresponding to some embodiments of act 1520.

At act 1530, a first encapsulation material is formed over the interposer, and then a first removal process is performed on the first encapsulation material to form a first encapsulant that encapsulates the die and the frame structure. FIG. 3 and FIG. 4 illustrates a cross-sectional view corresponding to some embodiments of act 1530.

At act 1540, a wafer saw process is performed along scribe lines to form multiple singulated structures. FIG. 5 illustrates a cross-sectional view corresponding to some embodiments of act 1540.

At act 1550, the singulated structure is disposed onto a wiring substrate to electrically connect to the wiring substrate. FIG. 6 illustrates a cross-sectional view corresponding to some embodiments of act 1550.

At act 1560, a second encapsulation material is formed over the wiring substrate, and then a second removal process is performed on the second encapsulation material to form a second encapsulant that encapsulates the singulated structure mounted on the wiring substrate. The second encapsulant may encapsulate the dies and the first encapsulant. FIG. 7 illustrates a cross-sectional view corresponding to some embodiments of act 1560.

At act 1570, a thermal interface material and an adhesive are applied to cover the singulated structure and the second encapsulant, and then a lid is attached to the thermal interface material and the adhesive. FIG. 8 illustrates a cross-sectional view corresponding to some embodiments of act 1570.

In accordance with some embodiments of the disclosure, a semiconductor package is provided. The semiconductor package includes an interposer and a die disposed on and electrically connected to the interposer. The semiconductor package further includes a first encapsulant disposed on the interposer and laterally encapsulating the die. The semiconductor package further includes a frame structure embedded in the first encapsulant.

In some embodiments, the frame structure has holes with a regular shape or an irregular shape. In some embodiments, a minimum inner diameter of the holes is greater than a maximum diameter of the particles in the first encapsulant. In some embodiments, the frame structure is attached to the interposer through an adhesive. In some embodiments, a minimum distance between the frame structure and the die is greater than or equal to 1 μm, and a minimum distance between the frame structure and an edge of the interposer is greater than or equal to 1 μm. In some embodiments, the frame structure includes a first mesh frame attached to an upper surface of the interposer and comprising first interconnected strips; and a second mesh frame attached to the first mesh frame and comprising second interconnected strips, wherein the first interconnected strips are distributed in a first plane substantially parallel to the upper surface of the interposer, and the second interconnected strips are distributed in a second plane substantially vertical to the upper surface of the interposer. In some embodiments, an angle between the first interconnected strip and the second interconnected strip is approximately between 80° and 100°. In some embodiments, the frame structure includes a metallic material or a polymer material. In some embodiments, the semiconductor package further includes an underfill disposed between the die and the interposer, wherein the underfill is surrounded by the frame structure.

In accordance with some other embodiments of the disclosure, a semiconductor package is provided. The semiconductor package includes a wiring substrate and a die disposed over and electrically connected to the wiring substrate. The semiconductor package further includes an interposer disposed between the die and the wiring substrate, wherein the die is electrically connected to the wiring substrate through the interposer. The semiconductor package further includes a frame structure disposed aside the die on the interposer. The semiconductor package further includes a first encapsulant disposed on the interposer and laterally encapsulating the die and the frame structure. The semiconductor package further includes a second encapsulant disposed on the wiring substrate, wherein the die and the first encapsulant are laterally encapsulated by the second encapsulant.

In some embodiments, a first top surface of the first encapsulant is substantially level with a second top surface of the second encapsulant, and a third top surface of the frame structure is below the first top surface of the first encapsulant. In some embodiments, the frame structure has a ring pattern surround the die in a top view. In some embodiments, the semiconductor package further includes an underfill disposed between the interposer and the wiring substrate, wherein the frame structure is vertically overlapped with the underfill.

In accordance with some other embodiments of the disclosure, a method of manufacturing a semiconductor package is provided. The method includes bonding a die onto an interposer to electrically connect to the interposer. The method further includes disposing a frame structure onto the interposer to surround the die. The method further includes forming a first encapsulation material over the interposer to encapsulate the die and the frame structure.

In some embodiments, the frame structure is located below an upper surface of the die. In some embodiments, the first encapsulation material is formed at a temperature below a glass transition temperature of the frame structure. In some embodiments, the method further includes applying an adhesive to a bottom surface of the frame structure before disposing the frame structure onto the interposer. In some embodiments, the method further includes performing a removal process to remove a portion of the first encapsulation material over the die such that the die is revealed and the frame structure is covered by the first encapsulation material. In some embodiments, the method further includes bonding the interposer onto a wiring substrate, wherein the frame structure is disposed between the first encapsulation material and the wiring substrate. In some embodiments, the method further includes forming a second encapsulation material over the wiring substrate to encapsulate the die, the frame structure and the first encapsulation material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer;
a die disposed on and electrically connected to the interposer;
a first encapsulant disposed on the interposer and laterally encapsulating the die; and
a frame structure embedded in the first encapsulant.

2. The semiconductor package according to claim 1, wherein the frame structure has holes with a regular shape or an irregular shape.

3. The semiconductor package according to claim 2, wherein a minimum inner diameter of the holes is greater than a maximum diameter of the particles in the first encapsulant.

4. The semiconductor package according to claim 1, wherein the frame structure is attached to the interposer through an adhesive.

5. The semiconductor package according to claim 1, wherein a minimum distance between the frame structure and the die is greater than or equal to 1 μm, and a minimum distance between the frame structure and an edge of the interposer is greater than or equal to 1 μm.

6. The semiconductor package according to claim 1, wherein the frame structure comprises:
a first mesh frame attached to an upper surface of the interposer and comprising first interconnected strips; and
a second mesh frame attached to the first mesh frame and comprising second interconnected strips,
wherein the first interconnected strips are distributed in a first plane substantially parallel to the upper surface of the interposer, and the second interconnected strips are distributed in a second plane substantially vertical to the upper surface of the interposer.

7. The semiconductor package according to claim 6, wherein an angle between the first interconnected strip and the second interconnected strip is approximately between 80° and 100°.

8. The semiconductor package according to claim 1, wherein the frame structure comprises a metallic material or a polymer material.

9. The semiconductor package according to claim 1 further comprising:
an underfill disposed between the die and the interposer, wherein the underfill is surrounded by the frame structure.

10. A semiconductor package, comprising:
a wiring substrate;
a die disposed over and electrically connected to the wiring substrate;
an interposer disposed between the die and the wiring substrate, wherein the die is electrically connected to the wiring substrate through the interposer;
a frame structure disposed aside the die on the interposer;
a first encapsulant disposed on the interposer and laterally encapsulating the die and the frame structure; and
a second encapsulant disposed on the wiring substrate, wherein the die and the first encapsulant are laterally encapsulated by the second encapsulant.

11. The semiconductor package according to claim 10, wherein a first top surface of the first encapsulant is substantially level with a second top surface of the second encapsulant, and a third top surface of the frame structure is below the first top surface of the first encapsulant.

12. The semiconductor package according to claim 10, wherein the frame structure has a ring pattern surrounding the die in a top view.

13. The semiconductor package according to claim 10 further comprising:
an underfill disposed between the interposer and the wiring substrate, wherein the frame structure is vertically overlapped with the underfill.

14. A method of manufacturing a semiconductor package, comprising:
bonding a die onto an interposer to electrically connect to the interposer;
disposing a frame structure onto the interposer to surround the die; and
forming a first encapsulation material over the interposer to encapsulate the die and the frame structure.

15. The method according to claim 14, wherein the frame structure is located below an upper surface of the die.

16. The method according to claim 14, wherein the first encapsulation material is formed at a temperature below a glass transition temperature or a melting point of the frame structure.

17. The method according to claim 14 further comprising:
applying an adhesive to a bottom surface of the frame structure before disposing the frame structure onto the interposer.

18. The method according to claim 14 further comprising:
performing a removal process to remove a portion of the first encapsulation material over the die such that the die is revealed and the frame structure is covered by the first encapsulation material.

19. The method according to claim 18 further comprising:
bonding the interposer onto a wiring substrate, wherein the frame structure is disposed between the first encapsulation material and the wiring substrate.

20. The method according to claim 19 further comprising:
forming a second encapsulation material over the wiring substrate to encapsulate the die, the frame structure and the first encapsulation material.
